(19) United States
(12) Patent Application Publication
(10) Pub. No.: US 2026/0320277 A1
(43) Pub. Date: Oct. 15, 2026

(54) SYSTEMS AND METHODS FOR IMPLEMENTING INTEGRATED CIRCUIT DESIGN

(71) Applicant: Taiwan Semiconductor Manufacturing Company, Ltd., Hsinchu (TW)

(72) Inventors: Yun-Chia Chen, Hsinchu (TW); Yu-Ze LIN, Hsinchu (TW); Huang-Yu Chen, Hsinchu (TW); King-Ho Tam, Hsinchu (TW); Chen-Jih LUI, Hsinchu (TW); Tze-Chiang Huan, Hsinchu (TW); Sandeep Kumar Goel, Hsinchu (TW)

(73) Assignee: Taiwan Semiconductor Manufacturing Company, Ltd., Hsinchu (TW)

(21) Appl. No.: 19/719,541

(22) Filed: Jun. 25, 2026

Related U.S. Application Data
(63) Continuation of application No. 18/472,725, filed on Sep. 22, 2023.

(51) Int. Cl. G06F 30/3947; G06F 30/392

(52) U.S. Cl. CPC G06F 30/3947; G06F 30/392

(57) ABSTRACT

An integrated circuit design implementation system includes a die-to-die (D2D) complier configured to receive a configuration of a semiconductor package. The semiconductor package includes a first semiconductor die and a second semiconductor die bonded to each other. The D2D compiler is configured to generate, based on the configuration of the semiconductor package, a first bump map and a second bump map for the first semiconductor die and the second semiconductor die, respectively. The first bump map indicates respective locations of a plurality of first bump structures of the first semiconductor die, and the second bump map indicates respective locations of a plurality of second bump structures of the second semiconductor die.

### CROSS-REFERENCE TO RELATED APPLICATION

This application is a continuation of U.S. Utility application Ser. No. 18/472,725, filed Sep. 22, 2023, the entire contents of which are incorporated herein by reference for all purposes.

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for advanced packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a processing system, in accordance with various embodiments of the present disclosure.

FIG. 2 illustrates a flow of an example method used by an electronic design automation (EDA), in accordance with some embodiments.

FIG. 3 illustrates a flow of an example method used by the EDA, in accordance with some embodiments.

FIG. 4 illustrates a flow of an example method used by the EDA, in accordance with some embodiments.

FIG. 5 illustrates an example bump map generated by the methods shown in FIG. 2 to FIG. 4 based on configuration of a semiconductor package, in accordance with some embodiments.

FIG. 6 illustrates example arrangements of semiconductor dies of a semiconductor package for which bump maps are generated, in accordance with some embodiments.

FIG. 7 illustrates example arrangements of semiconductor dies of a semiconductor package and corresponding bump maps, in accordance with some embodiments.

FIG. 8 illustrates example arrangements of semiconductor dies of a semiconductor package and corresponding bump maps, in accordance with some embodiments.

FIG. 9 illustrates a flow of an example method for configuring bump maps, in accordance with some embodiments.

FIG. 10 illustrates example operations for configuring bump maps, in accordance with some embodiments.

FIG. 11 illustrates example operations for configuring bump maps, in accordance with some embodiments.

FIG. 12 illustrates example operations for configuring bump maps, in accordance with some embodiments.

FIG. 13 illustrates an example operation for configuring bump maps, in accordance with some embodiments.

FIG. 14 illustrates an example operation for configuring bump maps, in accordance with some embodiments.

FIG. 15 illustrates an example bump map and a corresponding bit map, in accordance with some embodiments.

FIG. 16 illustrates example operations for designing a physical bump map, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A modern semiconductor device may be formed as a semiconductor package that includes a plurality of semiconductor dies (e.g., semiconductor chips, integrated circuit (IC) chips, etc.), operatively and physically coupled to one another. Various technologies are utilized to integrate multiple IC dies/chips into a single semiconductor package. Examples of semiconductor packages include a chip on wafer on substrate (CoWoS) package, an Integrated Fan-Out (InFo) package, a three-dimensional integrated circuit (3D IC) package, or the like. In a semiconductor package, different IC dies/chips (e.g., with logic functionality) are typically coupled to each other through one or more connection structures (e.g., without logic functionality). In the existing technologies, simulating and/or verifying such a semiconductor package typically requires a significant amount of human efforts. For example, after separately synthesizing lower-level circuit descriptions for the different IC dies/chips, physical arrangement and operative connection of the connection structures with respect to the IC dies/chips are manually configured for (e.g., inserted into) the synthesized lower-level circuit description. This manual efforts disadvantageously complicate the design and corresponding verification on a semiconductor package. Thus, the existing technologies to design a semiconductor package have not been entirely satisfactory in some aspect.

The present disclosure provides various embodiments of an integrated circuit design implementation system that can automatically generate design recipes based on a semiconductor package, and methods for operating the same. For example, the system can generate design recipes (e.g., a register-transfer level (RTL) map, a physical design (PD) map, a die-to-die (D2D) bump map), by for example, placing multi-stacking compatible bump structures, pre-placing clock structure scripts, etc. for 3D ICs (e.g., small outline integrated circuit (SoIC), InFO, 3D InFo, etc.) in a configurable way. The integrated circuit design implementation system described herein can include a D2D compiler. The D2D compiler can receive a configuration of a semiconductor package, the semiconductor package including at least a first semiconductor die and a second semiconductor die bonded to each other. The D2D compiler can generate, based on the configuration of the semiconductor package, a first bump map and a second bump map for the first semiconductor die and the second semiconductor die, respectively. The first bump map can indicate respective locations of a plurality of first bump structures of the first semiconductor die, and the second bump map can indicate respective locations of a plurality of second bump structures of the second semiconductor die. In the first bump map, a first subset of the first bump structures configured for transmitting signals to the second semiconductor die and a second subset of the first bump structures configured for receiving signals from the second semiconductor die are disposed symmetrically to each other with respect to an X-axis or a Y-axis of the first bump map. In the second bump map, a first subset of the second bump structures configured for transmitting signals to the first semiconductor die and a second subset of the second bump structures configured for receiving signals from the first semiconductor die are disposed symmetrically to each other with respect to an X-axis or a Y-axis of the second bump map.

The system, as disclosed herein, can automatically generate RTL description, bump maps, physical design layout, etc. by automatically generate recipes for D2D blocks based on different design specs/configurations (e.g., bump pitch, array size, etc.). This facilitates the design flow of 3D IC D2D interface blocks, thereby significantly help reducing time and efforts for designing a semiconductor package. The system, as disclosed herein, can generate front end (FE) RTL and back-end (BE) design recipes, for example, a 2.5-dimensional compatible bump map, 3D (front-to-front (F2F)/front-to-back (F2B)) compatible bump map, etc., as one of system outputs to support multi-stack designs. Such a bump map can support 3D IC multiple stacking splits (F2F, F2B, etc.) in a configurable/compatible way. This provides design flexibility, allowing for configurability and multi-stacking compatibility.

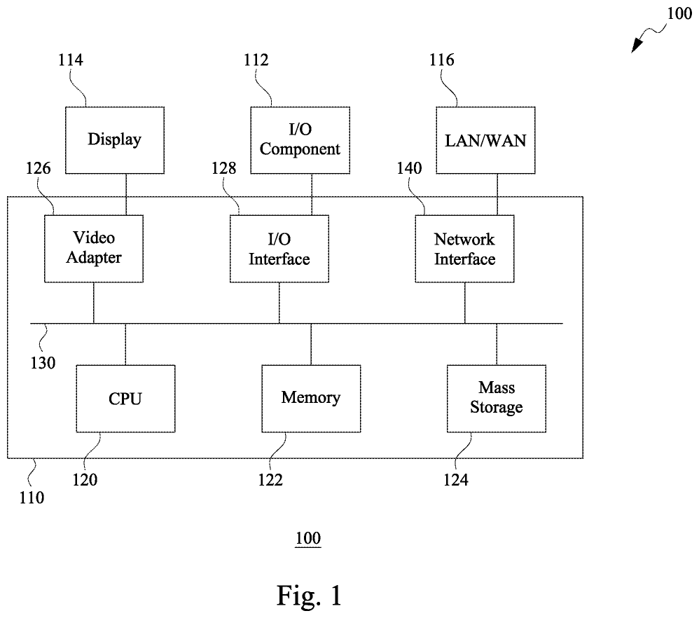

FIG. 1 illustrates a block diagram of a processing system 100 provided in accordance with various embodiments of the present disclosure. The processing system 100 can be used to implement any or all of the processes, steps, or operations discussed herein. The processing system 100 may include a processing tool 110, such as a desktop computer, a workstation, a laptop computer, or a dedicated unit customized for a particular application. The processing system 100 may be equipped with a display 114 and one or more input/output devices 112, such as a mouse, a keyboard, or printer. The processing tool 110 may include a central processing unit (CPU) 120, memory 122, a mass storage device 124, a video adapter 126, and an I/O interface 128 connected to a bus 130.

The bus 130 may be one or more of any type of several bus architectures including a memory bus or memory controller, a peripheral bus, or video bus. The CPU 120 may include any type of electronic data processor, and the memory 122 may comprise any type of system memory, such as static random access memory (SRAM), dynamic random access memory (DRAM), or read-only memory (ROM).

The mass storage device 124 may include any type of storage device configured to store data, programs, and other information and to make the data, programs, and other information accessible via the bus 130. The mass storage device 124 may include, for example, one or more of a hard disk drive, a magnetic disk drive, an optical disk drive, or the like.

The video adapter 126 and the I/O interface 128 provide interfaces to couple external input and output devices to the processing tool 110. As illustrated in FIG. 1, examples of input and output devices include the display 114 coupled to the video adapter 126 and the I/O device 112, such as a mouse, keyboard, printer, and the like, coupled to the I/O interface 128. Other devices may be coupled to the processing tool 110, and additional or fewer interface cards may be utilized. For example, a serial interface card (not shown) may be used to provide a serial interface for a printer. The processing tool 110 also may include a network interface 140 that may be a wired link to a local area network (LAN) or a wide area network (WAN) 116 and/or a wireless link.

It should be noted that the processing system 100 may include other components. For example, the processing system 100 may include power supplies, cables, a motherboard, removable storage media, cases, and the like. These other components, although not shown, are considered part of the processing system 100.

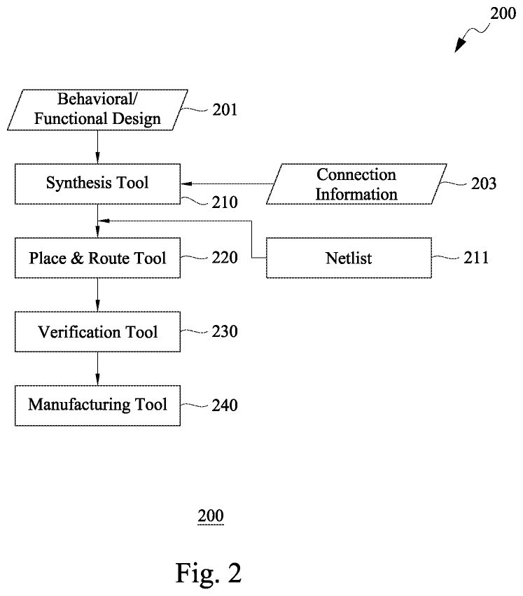

In various embodiments of the present disclosure, an electronic design automation (EDA) is program code that is executed by the CPU 120 to automatically generate a netlist based on the design of a semiconductor package (described further below with respect to FIG. 2). Further, during the execution of the EDA, the EDA may provide various analysis and/or verification on the semiconductor package based on a layout of the automatically generated netlist. The program code may be accessed by the CPU 120 via the bus 130 from the memory 122, mass storage device 124, or the like, or remotely through the network interface 140.

FIG. 2 illustrates a flow of an example method 200 used by the disclosed EDA in an embodiment of the present disclosure to automatically generate or update a netlist based on the design of a semiconductor package and user-supplied/specified behavioral/functional design 201 and connection information 203. In various embodiments of the present disclosure, the semiconductor package includes a plural number of IC chips (hereinafter “logic chips”) and a plural number of connection structures (“non-logic structures”). Specifically, the logic chips can each present one or more logic and/or analog functions, while the non-logic structures can each provide one or more electrical connection functions for corresponding ones of the logic chips.

For example, the behavioral/functional design 201 can specify the desired behavior or function of the logic chips based upon various signals or stimuli applied to inputs of the overall design, and may be written in a suitable language, such as a hardware description language (HDL). The behavioral/functional design 201 may be uploaded into the processing tool 110 (see FIG. 1) through the I/O interface 128, such as by a user creating the file while the EDA is executing. Alternatively, the behavioral/functional design 201 may be uploaded and/or saved on the memory 122 or mass storage device 124, or the behavioral/functional design 201 may be uploaded through the network interface 140 from a remote user (see FIG. 1). In these instances, the CPU 120 will access the behavioral/functional design 201 during execution of the EDA.

The connection information 203 can specify physical arrangement and connectivity among the logic chips and the non-logic structures, in accordance with various embodiments of the present disclosure. For example, the connection information 203 can include how the logic chips are physically arranges with one another, e.g., side-by-side, on top of one another, or combinations thereof. In another example, the connection information 203 can include how different ones of the logic chips are electrically coupled to each other. Based on the techniques to form the semiconductor package, the non-logic structures can include any of various structures that can provide electrical connection function and/or mechanical support. Examples of the non-logic structures include a physical substrate (e.g., a printed circuit board (PCB), a chip scale package (CSP) substrate), a physical redistribution layer (RDL), and a physical interposer (e.g., a silicon interposer, an organic interposer, etc.). Similar to the behavioral/functional design 201, the connection information 203 may be uploaded into the processing tool 110 (see FIG. 1) through the I/O interface 128, such as by a user creating the file while the EDA is executing. Alternatively, the connection information 203 may be uploaded and/or saved on the memory 122 or mass storage device 124, or the behavioral/functional design 201 may be uploaded through the network interface 140 from a remote user (see FIG. 1). In these instances, the CPU 120 will access the connection information 203 during execution of the EDA.

The EDA can take the behavioral/functional design 201 and the connection information 203, and perform a synthesis, e.g., by a synthesis tool 210, to generate a netlist, e.g., 211. In a brief overview, the synthesis tool 210 can first form a number of functionally equivalent logic gate-level circuit descriptions (hereinafter “first netlists”) corresponding to the logic chips, respectively, based on the behavioral/functional design 201. It should be noted that such first netlists can each represent a gate-level description for the corresponding individual logic chip. Next, the synthesis tool 210 can transform the first netlists to the netlist 211 (hereinafter “second netlist”), which includes how the logic chips are physically arranged and operatively communicated with each other through the non-logic structures, based on the connection information 203. The synthesis tool 210 can generate the second netlist based on a graph, including a number of vertices connected to one another through corresponding ones of edges, which will be discussed as follows.

According to various embodiments of the present disclosure, while generating the first netlists (for the logic chips), the synthesis tool 210 can convert the logic chips into a number of first vertices, respectively. Next, upon receiving the connection information 203 (specifying the non-logic structures), the synthesis tool 210 can convert the non-logic structures into a number of second vertices, respectively. For example, the synthesis tool 210 may arrange the second vertices and the first vertices according to the physical arrangement specified in the connection information 203. Next, the synthesis tool 210 can generate a number of third vertices, each of which corresponds to a virtual interface between any two of the logic chips and the non-logic structures. Next, the synthesis tool 210 can connect two of the first vertices, second vertices, and/or third vertices through a number of edges. For example, the synthesis tool 210 may generate or otherwise configured such edges according to the connectivity (among the logic chips and the non-logic structures) specified in the connection information 203. As a result, a graph consisting of the first vertices, second vertices, third vertices, and edges can be formed. The synthesis tool 210 can determine this graph uniquely corresponding to the semiconductor package. As a result, the synthesis tool 210 can automatically transform the first netlists as the second netlist 211.

In some embodiments, the synthesis tool 210 can provide the second netlist 211 to a place and route tool 220. Based on the second netlist 211, the place and route tool 220 can create an actual physical design for the overall structure (e.g., the semiconductor package) and/or bump maps for semiconductor dies of the semiconductor package. The place and route tool 220 can form the physical design by taking chosen cells from cell libraries and placing them into cell rows, thereby creating a bump map. These cell rows generally have a row height similar to the height of a majority of the individual cells located within that cell row such that the power rails, implants and wells may be aligned between the individual cells. The placement of each individual cell within the cell rows, and the placement of each cell row in relation to other cell rows, may be guided by cost functions in order to minimize wiring lengths and area requirements of the resulting integrated circuit. This placement may be done either automatically by the place and route tool 220, or else may alternatively be performed partly through a manual process, whereby a user may manually insert one or more cells into a row.

Once the placement and route tool 220 finishes generating the actual physical design for the overall structure, a verification tool 230 can provide a physical verification of the semiconductor package. The physical verification generally includes a timing verification, a design rule check (DRC), a layout versus schematic (LVS) analysis, and an electrical rule check (ERC). Once the physical verification is completed with satisfactory results, the design of the semiconductor package can be sent to a manufacturing tool 240 to generate, e.g., photolithographic masks, that may be used in the physical manufacture of the desired design. The design may be sent to the manufacturing tool 240 through that LAN/WAN 116 (FIG. 1) or other suitable forms of transmission from the EDA to the manufacturing tool 240.

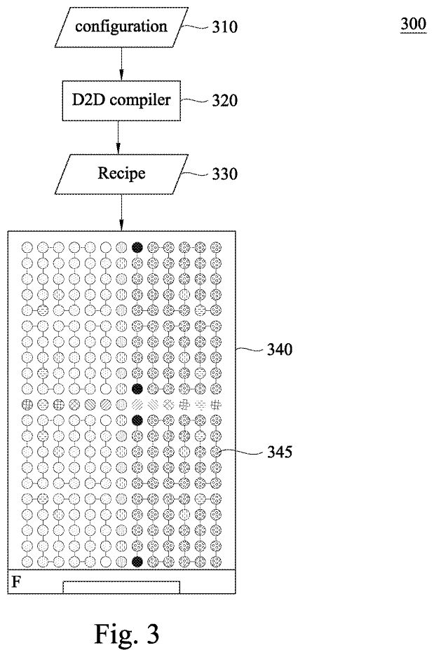

FIG. 3 illustrates a flow of an example method 300 used by the EDA, in accordance with some embodiments of the present disclosure to automatically generate a bump map 340 of a semiconductor package based on configuration 310 (e.g., user-supplied/specified behavioral/functional design 201 and connection information 203, etc.). The configuration 310 includes information or specification file to design an actual physical design for an overall structure of a semiconductor package and/or bump maps for semiconductor dies in the semiconductor package. In some examples, the configuration 310 may include various information of the semiconductor dies, including but not limited to, a number of data bits, a size of a bump matrix, a repair-data ratio, a Dynamic Bus Inversion (DBI)-data ratio, a Power Ground (PG) ratio, etc.

The configuration 310 can be uploaded into the processing tool 110 (see FIG. 1) through the I/O interface 128, such as by a user creating the file while the EDA is executing. In response to uploading (or receipt) of the configuration 310, the processing tool 110 and/or a die-to-die (D2D) compiler 320 located thereon can generate a recipe 330. The D2D compiler can be operably coupled to the synthesis tool 210 and the place and route tool 220 to generate the recipe 330. Based on the recipe 330, the processing tool 110 and/or the D2D compiler 320 can generate a register-transfer level (RTL) map, a physical design (PD) map, a D2D bump map, etc. The bump map 340 is shown as a non-limiting example of a bump map that can be generated by the D2D compiler.

As shown in the bump map 340, cells are selected to form different subsets of bump structures 345, and each of different subsets of bump structures can have a different function (e.g., transmitting signals, receiving signals, etc.). The bump structures 345 filled with different patterns indicate bump structures with different functions. While briefly described herein as an example, different bump maps and structures will be described below in greater detail.

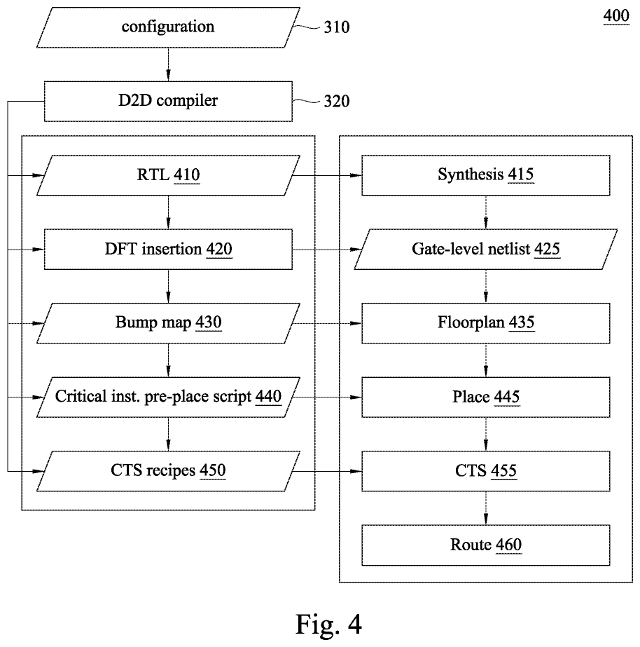

FIG. 4 illustrates a flow of an example method 400 used by the EDA, in accordance with some embodiments of the present disclosure to automatically design a recipe (e.g., the recipe 330) based on configuration 310 (e.g., user-supplied/specified behavioral/functional design 201 and connection information 203, etc.).

The configuration 310 can include various information of the semiconductor dies, including but not limited to, data-byte ratio, a number of data bits, a size of a bump matrix, a repair-data ratio, a Dynamic Bus Inversion (DBI)-data ratio, a Power Ground (PG) ratio, etc. A non-limiting example of the configuration 310 may include a data-byte ratio of 32, a DBI-data ratio of 1/8, and a repair-data ratio of 1/32, etc.

The D2D compiler 320 can receive the configuration 310 and perform a synthesis 415 (e.g., by the synthesis tool 210) based on the configuration 310. The configuration 310 can include library kits files (e.g., library exchange format (LEF), gds (graphic data stream), etc.) and configurable design specification (e.g., FP dimension, a bump array matrix (e.g., a size thereof), a bump X/Y pitch, a Power Ground (PG) ratio, a Dynamic Bus Inversion (DBI)-data ratio, a repair-data bit ratio, design for testing (DFT) data, data bits (e.g., a number of data bits), 3D port, LITEIO, FF name, etc.). The synthesis tool 210 and/or the D2D compiler 320 operatively coupled thereto can generate a gate-level netlist 425 based on an RTL description 410 (e.g., generated by the D2D compiler 320 or included in the configuration 310). In some examples, the configuration 310 may include DFT data, and the synthesis tool 210 and/or the D2D compiler 320 operatively coupled thereto can perform a DFT insertion 420 to add an additional logic process to improve testability of the recipe design. In some examples, the RTL description 410 may include LITEIO module that includes LITEIO cells and transmits and receives clock/control/data IOs, RP_REG module that calculates repair/DBI cells, and DESKEW-FIFO module that handles clock domain crossing in stack-level timing. In some examples, the D2D compiler 320 can generate the RTL description at least based on the number of data bits, the DBI-data ratio, and the repair-data ratio.

Based on the gate level netlist 425 and bump map description 430, the D2D compiler 320 can create a floorplan 435. The bump map description 430 can include, but not limited to, a bump array matrix, a size thereof, a bump X/Y pitch, etc., and the D2D compiler can generate the floorplan 435 for an actual physical design for an overall structure of the semiconductor package and/or bump maps for semiconductor dies.

Based on critical inst. pre-place script 440 and the floorplan 435, a place and route tool (e.g., 220) and/or the D2D compiler 320 operably coupled thereto can create (place 445 and route 460) an actual physical design for the overall structure (e.g., the semiconductor package) and/or bump maps for semiconductor dies included in the semiconductor package. The place and route tool (e.g., 220) can form the physical design by taking chosen cells from cell libraries and placing them into cell rows, thereby creating bump structures. As discussed in greater detail below, bump structures can include various subsets of bump structures (e.g., bump structures for transmitting signals, bump structures for receiving signals, etc.). The place and route tool 220 (e.g., automatic place & route (APR)) and/or the D2D compiler 320 operably coupled thereto can perform a specific standard cells placement according to the critical instance preplace script, and perform the distribution of the clock tree according to the clock tree synthesis (CTS) recipes.

This placement and routing may be done either automatically by the place and route tool (e.g., 220), or else may alternatively be performed partly through a manual process, whereby a user may manually insert one or more cells into a row.

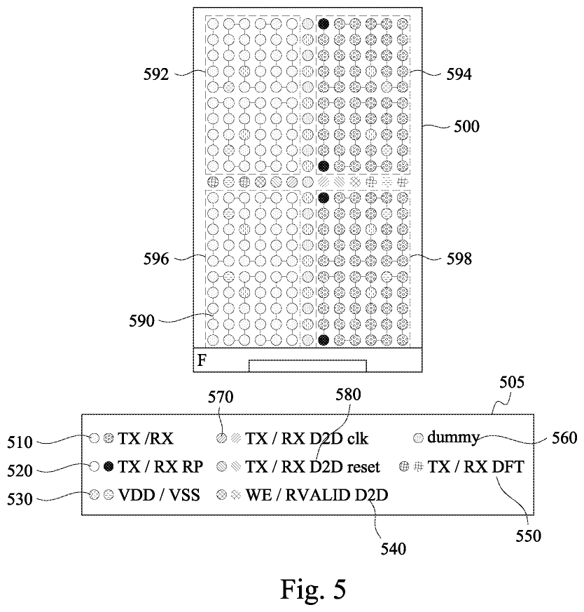

FIG. 5 illustrates an example bump map 500 generated by the methods shown in FIG. 2 to FIG. 4 based on configuration of a semiconductor package, in accordance with some embodiments. A D2D complier (e.g., 320) can receive a configuration of a semiconductor package, the semiconductor package including at least a first semiconductor die and a second semiconductor die bonded to each other. The D2D compiler (e.g., 320) can generate, based on the configuration of the semiconductor package, the bump map 500 (e.g., a first bump map for the first semiconductor die, a second bump map for the second semiconductor die, etc.). The bump map 500 indicates respective locations of various bump structures of the semiconductor die. As shown in FIG. 5, the various bump structures can be arranged in various ways. In some examples, a subset of the bump structures can be disposed symmetrically to each other with respect to an X-axis or a Y-axis of the bump map 500. In some examples, a subset of the bump structures can be disposed in parallel with the X-axis of the bump map 500, where the bump structures are spaced from one another with a predetermined distance of a plurality of predetermined different distances (e.g., first distance, second distance, etc.). In some examples, a subset of the bump structures can be disposed on the X-axis or the Y-axis of the bump map 500.

The bump map 500 includes various subsets of bump structures, each of the subsets include bump structures for different functions, as shown in a legend 505. TX/RX 510 is a bump structure for transmitting/receiving a signal to/from another bump structure. For example, a TX bump structure can transmit a signal to a RX bump structure. TX/RX RP 520 is a bump structure for repairing. VDD/VSS 530 is a bump structure for supplying/receiving/grounding a voltage. TX/RX D2D clk 570 is a bump structure to transfer the clock signal between dies. TX/RX D2D reset 580 is a bump structure for resetting a device or circuit to its default state or initial condition. WE/RVALID D2D 540 is a bump structure for ensuring the data is correctly written and read from a memory or a register. TX/RX DFT 550 is a bump structure to facilitate testing of integrated circuits. Dummy 560 is a dummy bump structure.

In some examples, as shown in FIG. 5, a plurality of subsets of the bump structures can be configured as a plurality of repair chains disposed in a corresponding zone of the bump map 500. Each zone can occupy M times an area unit of the bump map 500, where M is a positive integer. In some examples, different bump structures can form different subsets of the bump structures. For example, a first subset of first bump structures configured as a plurality of first repair chains are each disposed in a corresponding first zone 592 of a first bump map, and a second subset of the first bump structures further configured as a plurality of second repair chains are each disposed in a corresponding second zone 594 of the first bump map. The first zone 592 and the second zone 594 can each occupy M times an area unit of the first bump map, M being a positive integer. In some examples, a first subset of second bump structures configured as a plurality of third repair chains are each disposed in a corresponding third zone 596 of a second bump map, and a second subset of the second bump structures further configured as a plurality of fourth repair chains are each disposed in a corresponding fourth zone 598 of the second bump map. The third zone 596 and the fourth zone 598 can each occupy N times an area unit of the second bump map, N being a positive integer. In some examples, the integers M and N may be 24, 16, 8, etc.

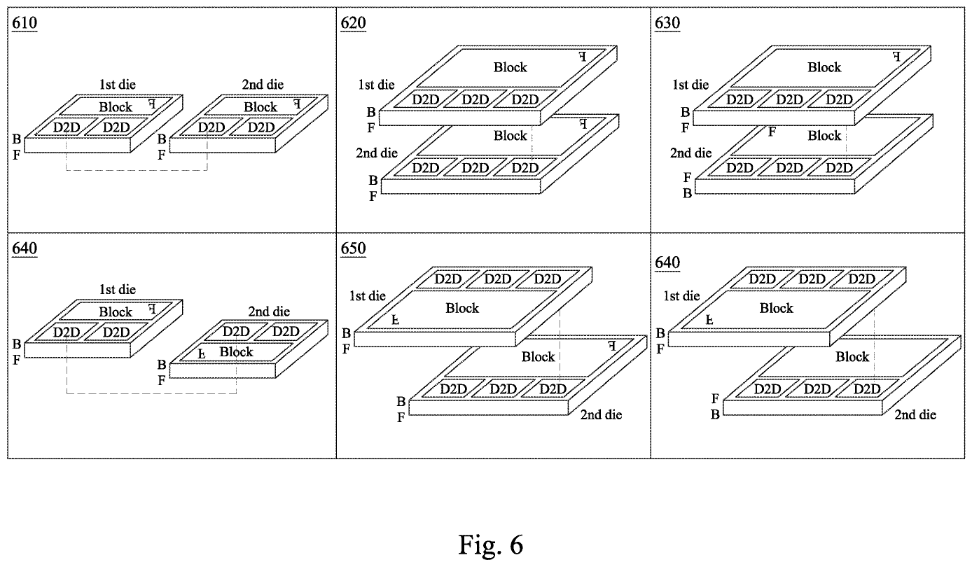

FIG. 6 illustrates example arrangements 600 of semiconductor dies of a semiconductor package for which bump maps are generated, in accordance with some embodiments. The D2D compiler (e.g., 320) described herein can output bump maps for semiconductor dies with various arrangements 600. In some examples, the D2D compiler (e.g., 320) described herein can generate bump maps for semiconductor dies with multi-stacking arrangements. The arrangements 600 are merely non-limiting examples, and the D2D compiler (e.g., 320) described herein can output bump maps for semiconductor dies with other arrangements.

The arrangements 610, 620, and 630 show full stack arrangements where a first die and a second die are arranged along an axis. In the arrangement 610, the first die and the second die are arranged side by side (e.g., 2.5D full stack). In the arrangement 620, the first die and the second die are vertically stacked to one another, such that the front side of the first die faces the back side of the second die (e.g., 3D F2B full stack). In the arrangement 630, the first die and the second die are vertically stacked to one another, such that the front side of the first die faces the front side of the second die (e.g., 3D F2F full stack).

The arrangements 640, 650, and 660 show partial stack arrangements where a first die and a second die are arranged off-axis. In the arrangement 640, the first die and the second die are arranged side by side (e.g., 2.5D partial stack). In the arrangement 650, the first die and the second die are vertically, but partially, stacked to one another, such that the front side of the first die faces the back side of the second die (e.g., 3D F2B partial stack). In the arrangement 660, the first die and the second die are vertically, but partially, stacked to one another, such that the front side of the first die faces the front side of the second die (e.g., 3D F2F partial stack).

Although the arrangements 600 show two semiconductor dies, in some examples, the D2D compiler (e.g., 320) described herein can generate bump maps compatible with more than two semiconductor die.

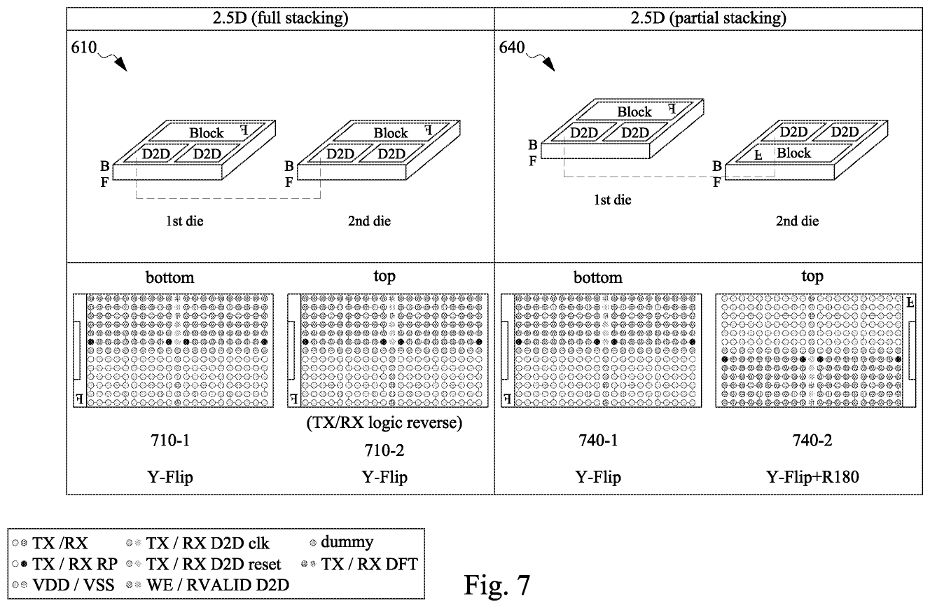

FIG. 7 illustrates example arrangements 610, 640 (shown in FIG. 6) of semiconductor dies of a semiconductor package and corresponding bump maps 710 (710-1 and 710-2), 740 (740-1 and 740-2), in accordance with some embodiments. The bump map 710-1 is a bump map corresponding to the first semiconductor die in the arrangement 610, and the bump map 710-2 is a bump map corresponding to the second semiconductor die in the arrangement 610. The bump map 740-1 is a bump map corresponding to the first semiconductor die in the arrangement 640, and the bump map 740-2 is a bump map corresponding to the second semiconductor die in the arrangement 640.

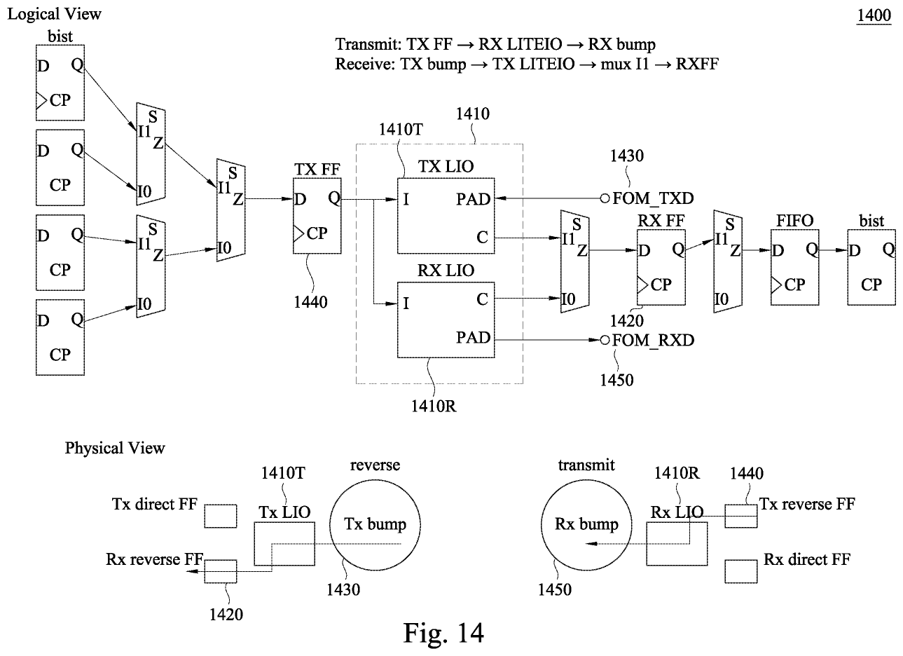

The D2D compiler (e.g., 320) can automatically generate the bump maps 710 based on the arrangement 610 and generate the bump maps 740 based on the arrangement 640. As shown in the bump maps 740, the RX structures and the TX structures of the bump map 740-1 are to be respectively connected to the TX structures and the RX structures of the bump map 740-2, to communicate signals therebetween. As shown in the bump maps 710, a “reverse” logic can be used to generate the bump map 710 such that the RX structures and the TX structures of the bump map 710-1 are to be respectively connected to the RX structures and the TX structures of the bump map 710-2, to communicate signals therebetween. The “reverse” logic will be discussed in greater detail with respect to FIG. 14.

As discussed herein, the bump maps (e.g., 710-1, 710-2, 740-1, 740-2, etc.) can be arranged according to the corresponding arrangements (e.g., 610, 640, etc.). The bump maps can be generated without changing a location of individual bump structures. Instead, a relative arrangement (e.g., orientation, symmetry, etc.) of the bump maps can be changed (e.g., rotation, flipping, etc.) according to the corresponding arrangement.

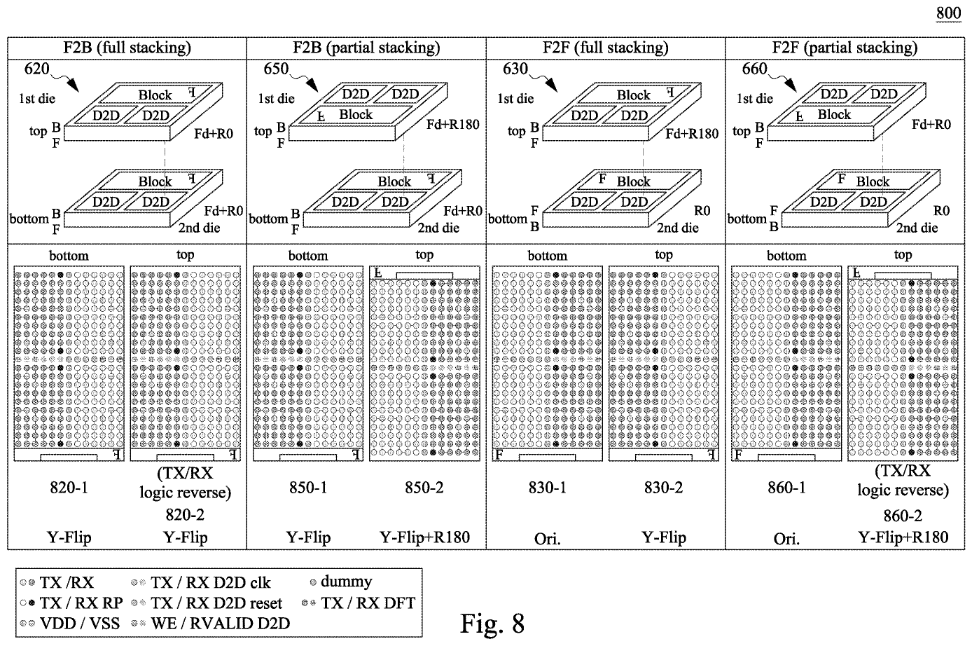

FIG. 8 illustrates example arrangements 620, 650, 630, 660 (shown in FIG. 6) of semiconductor dies of a semiconductor package and corresponding bump maps 820 (820-1 and 820-2), 850 (850-1 and 850-2), 830 (830-1 and 830-2), 860 (860-1 and 860-2) in accordance with some embodiments. The bump map 820-1 is a bump map corresponding to the first semiconductor die in the arrangement 620, and the bump map 820-2 is a bump map corresponding to the second semiconductor die in the arrangement 620. The bump map 850-1 is a bump map corresponding to the first semiconductor die in the arrangement 650, and the bump map 850-2 is a bump map corresponding to the second semiconductor die in the arrangement 650. The bump map 830-1 is a bump map corresponding to the first semiconductor die in the arrangement 630, and the bump map 830-2 is a bump map corresponding to the second semiconductor die in the arrangement 630. The bump map 860-1 is a bump map corresponding to the first semiconductor die in the arrangement 660, and the bump map 860-2 is a bump map corresponding to the second semiconductor die in the arrangement 660.

The D2D compiler (e.g., 320) can automatically generate the bump maps 820, 850, 830, 860 respectively based on the arrangement 620, 650, 630, 660. In the arrangement 620, the bump map 820-1 corresponds to the second semiconductor die in the arrangement 620, and the bump map 820-2 corresponds to the first semiconductor die in the arrangement 620. Since the arrangement 620 is arranged front-to-back (F2B) (e.g., a front surface of the first semiconductor die faces a back surface of the second semiconductor die), the bump map 820-2 reflects the front surface of the first semiconductor die, and the bump map 820-1 reflects the back surface of the second semiconductor die. Since the arrangement 620 is a full stacking arrangement, where the two semiconductor dies are arranged along an axis, the bump structures in the bump map 820-1 are positioned in accordance with the locations of the bump structures in the bump map 820-2. That is, the bump structures in the bump map 820-2 are located at the locations corresponding to the locations of the bump structures in the bump map 820-1. In the arrangement 620, the “reverse” logic is used such that the RX structures and the TX structures of the bump map 820-1 are to be respectively connected to the RX structures and the TX structures of the bump map 820-2, to communicate signals therebetween.

In the arrangement 630, the bump map 830-1 corresponds to the second semiconductor die in the arrangement 630, and the bump map 830-2 corresponds to the first semiconductor die in the arrangement 630. Since the arrangement 630 is arranged front-to-front (F2F), the bump map 830-2 reflects the front surface of the first semiconductor die, and the bump map 830-1 reflects the front surface of the second semiconductor die. Since the arrangement 630 is a full stacking arrangement, where the two semiconductor dies are arranged along an axis (vertical axis here), the bump structures in the bump map 830-1 are positioned in accordance with the locations of the corresponding bump structures in the bump map 830-2. That is, the bump structures in the bump map 830-2 are located at the same locations as the locations of the corresponding bump structures in the bump map 830-1. In the arrangement 630, the “reverse” logic is not used, so that the RX structures and the TX structures of the bump map 830-1 are to be respectively connected to the TX structures and the RX structures of the bump map 830-2, to communicate signals therebetween.

In the arrangement 650, the bump map 850-1 corresponds to the second semiconductor die in the arrangement 650, and the bump map 850-2 corresponds to the first semiconductor die in the arrangement 650. Since the arrangement 650 is arranged front-to-back (F2B), the bump map 850-2 reflects the front surface of the first semiconductor die, and the bump map 850-1 reflects the back surface of the second semiconductor die. Since the arrangement 650 is a partial stacking arrangement, where the two semiconductor dies are off-axis, the bump structures in the bump map 850-1 are positioned according to the corresponding locations of the bump structures in the bump map 850-2. For example, as shown, the bump map 850-2 can be rotated such that the bump structures in the bump map 850-1 are positioned according to the corresponding locations of the bump structures in the bump map 850-2. In the arrangement 650, the “reverse” logic is not used, so the RX structures and the TX structures of the bump map 850-1 are to be respectively connected to the TX structures and the RX structures of the bump map 850-2, to communicate signals therebetween.

In the arrangement 660, the bump map 860-1 corresponds to the second semiconductor die in the arrangement 660, and the bump map 860-2 corresponds to the first semiconductor die in the arrangement 660. Since the arrangement 660 is arranged front-to-front (F2F), the bump map 860-2 reflects the front surface of the first semiconductor die, and the bump map 860-1 reflects the front surface of the second semiconductor die. Since the arrangement 660 is a partial stacking arrangement, where the two semiconductor dies are off-axis, the bump structures in the bump map 860-1 are positioned according to the corresponding locations of the bump structures in the bump map 860-2. For example, as shown, the bump map 860-2 can be rotated such that the bump structures in the bump map 860-1 are positioned according to the corresponding locations of the bump structures in the bump map 860-2. In the arrangement 660, the “reverse” logic is used such that the RX structures and the TX structures of the bump map 860-1 are to be respectively connected to the RX structures and the TX structures of the bump map 860-2, to communicate signals therebetween.

As discussed herein, the bump maps (e.g., 820-1, 820-2, 850-1, 850-2, 830-1, 830-2, 860-1, 860-2, etc.) can be arranged according to the corresponding arrangements (e.g., 620, 650, 630, 660, etc.). The bump maps can be generated without changing a location of individual bump structures. Instead, a relative arrangement (e.g., orientation, symmetry, etc.) of the bump maps can be changed (e.g., rotation, flipping, etc.) according to the corresponding arrangement.

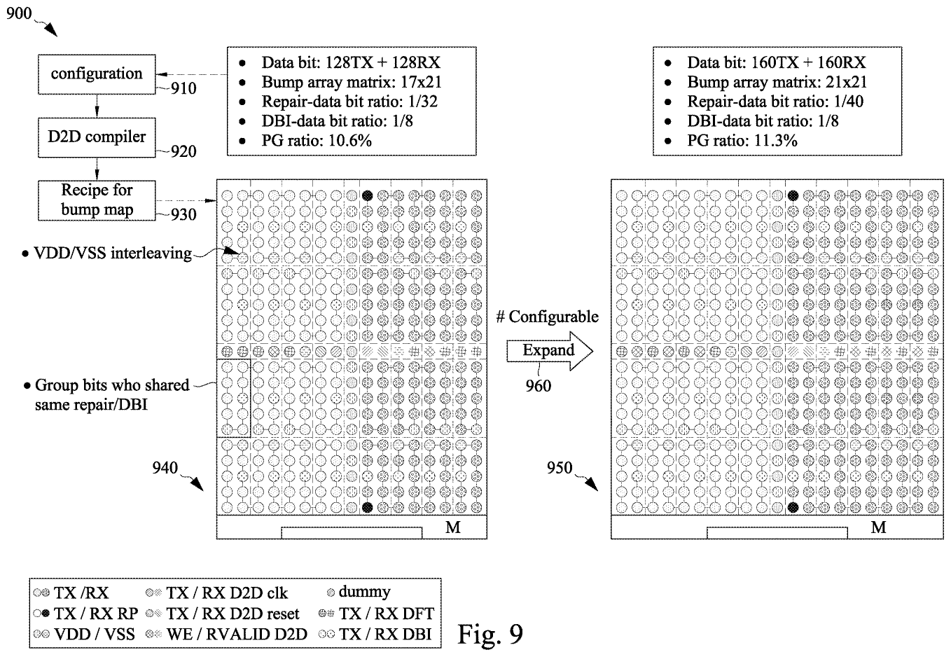

FIG. 9 illustrates a flow of an example method 900 for configuring bump maps, in accordance with some embodiments. The method 900 may be substantially similar or identical to the method 300. The configuration 910 may be substantially similar or identical to the configuration 310. The D2D compiler 920 may be substantially similar or identical to the D2D compiler 320. The recipe 930 may be substantially similar or identical to the recipe 330.

The method 900 may include configuring or re-configuring the initial bump map 940. The configuration 910 may include configuration to expand 960 the initial bump map 940 into an expanded bump map 950. As shown in FIG. 9, the initial bump map 940 is generated based on configurations including: data bit of 128TX+128RX, a bump array matrix of 17×21, a repair-data bit ratio of 1/32, a DBI-data bit ratio of 1/8, and a PG ratio of 10.6%. The D2D compiler 920 can re-configure (e.g., expand 960) the initial bump map 940 to generate the expanded bump map 950, based on updated configuration (e.g., configuration to expand). For example, the expanded bump map 950 is generated based on the updated configuration including: data bit of 160TX+160RX, a bump array matrix of 21×21, a repair-data bit ratio of 1/40, a DBI-data bit ratio of 1/8, and a PG ratio of 11.3 %. To achieve the re-configuration (e.g., expansion), various operations can be performed on the bump structures. For example, as shown in FIG. 9, different subsets of the bump structures can be interleaved, grouped, symmetrically arranged, etc.

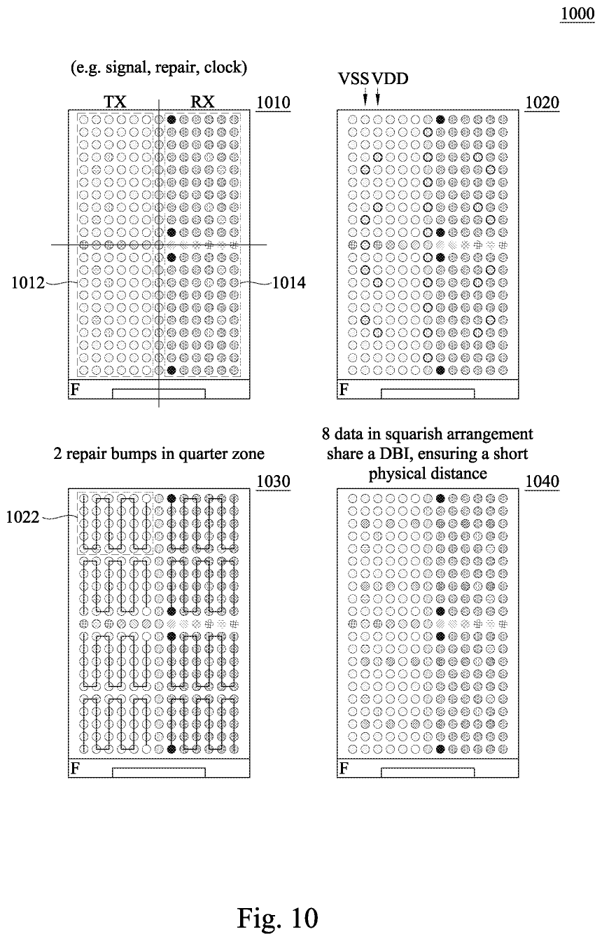

FIG. 10 illustrates example operations 1000 for configuring bump maps, in accordance with some embodiments. The D2D compiler (e.g., 320) can perform at least one of the operations 1000 to configure (e.g., generate a bump map) or re-configure (e.g., expand) a bump map. In operation 1010, bump structures can be paired. As a non-limiting example, the operation 1010 is shown to pair TX/RX bump structures 1012, 1014 such that the bump structures 1012, 1014 are located symmetrically with respect to the Y-axis and the X-axis. More specifically, the TX structures 1012 are located on a left-hand side of the bump map, and the RX structures 1014 are located on a right-hand side of the bump map, wherein the TX and RX structures 1012, 1014 are symmetrical with respect to the Y axis. On the X axis and the Y axis, the bump structures for transmitting/receiving a control signal, VDD/VSS, etc. are located (e.g., TX/RX D2D clk, Tx/Rx D2D reset, TX/RX DFT, etc.).

In operation 1020, the bump structures for interleaving VDD/VSS can be positioned to form a balanced interleaved multiple power supply. This allows for stable and reliable power grid and improved IR performance (e.g., reducing voltage drop, IR drop, etc.).

In operation 1030 and operation 1040, bump structures that are highly related bits can be grouped. In the operation 1030, the bump structures that share same repair chain 1022 (and/or share same bus encoding) can be grouped. As shown in FIG. 10, the operation 1030 can group the bump structures into a plurality of groups. In the operation 1040, the bump structures can be grouped such that N (e.g., N=8, 10, . . . ) data in squarish arrangement share a DBI for a short physical distance. As described herein, the symmetrical bump structures allow for flexible configuration/arrangement/re-configuration (e.g., rotation, flip, etc.) of bump maps, thereby saving time and manpower in overall processes for 3D IC stacking.

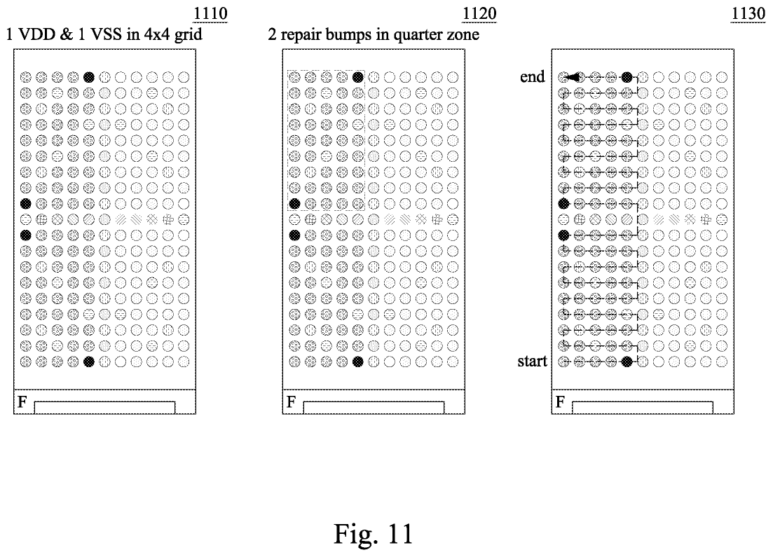

FIG. 11 illustrates example operations 1100 for configuring bump maps, in accordance with some embodiments. The D2D compiler (e.g., 320) can perform at least one of the operations 1100 to configure (e.g., generate a bump map) or re-configure (e.g., expand) a bump map. In operation 1110, bump structures for VDD/VSS can be placed based on a Power Ground (PG) ratio. The bump structures for VDD/VSS can be placed within a predetermined size of sub-grid (N×M where N and M are integers; e.g., N=4, M=4) to satisfy a PG ratio. Shown in the operation 1110 of FIG. 11 is a non-limiting example, and any PG ratio can be achieved by placing the bump structures for VDD/VSS within a different size of sub-grid. As shown in FIG. 11, the bump structures for VDD/VSS can be symmetrically located with respect to the X-axis and/or the Y-axis of the bump map.

In operation 1120, bump structures for repairing can be placed within a predetermined location of the bump map. For example, as shown in the operation 1120 of FIG. 11, the bump structures for repairing can be placed within a quarter zone. In some examples, the bump structures for repairing can be placed within a predetermined location of the bump map thereby satisfying a predetermined repair-data ratio. For example, the bump structures for repairing can be placed close to the corresponding repair chain to improve the efficiency of the repair process. The bump structures for repairing can be symmetrically located with respect to the X-axis and/or the Y-axis of the bump map.

In operation 1130, bump structures in a predetermined zone of the bump map can form a sequence for Dynamic Bus Inversion (DBI). For example, as shown in the operation 1130 of FIG. 11, the bump structures located within the left-hand side of the bump map form a sequence, starting from the bottom portion of the bump map and ending at the top portion of the bump map, for DBI. In some examples, a predetermined number of bump structures can be sequenced for DBI to satisfy a predetermined a DBI-data ratio. In some examples, a first subset and a second subset of bump structures can be further configured as a plurality of first DBI signals and can be each disposed in a corresponding first zone of the bump map. In some examples, the first zone each occupies M times an area unit of the first bump map, M being a positive integer.

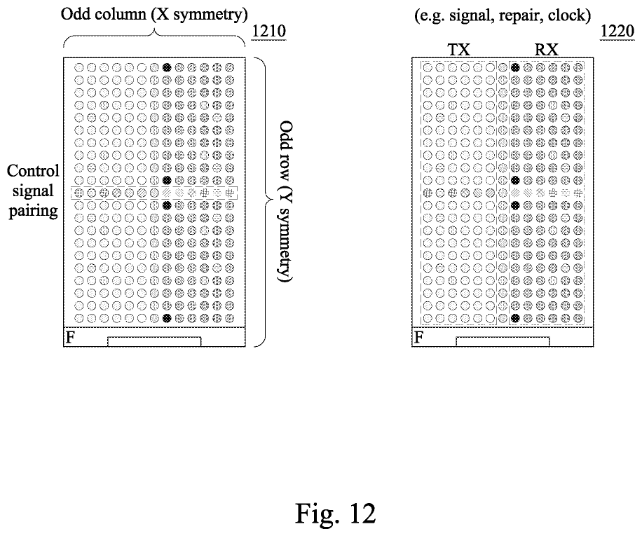

FIG. 12 illustrates example operations 1200 for configuring bump maps, in accordance with some embodiments. The D2D compiler (e.g., 320) can perform at least one of the operations 1200 to configure (e.g., generate a bump map) or re-configure (e.g., expand) a bump map. In operation 1210, the D2D compiler can configure an N×M bump map where N and M are odd integers. This allows for placement of bump structures for control signal pairing at the central row (e.g., the X-axis of the bump map) and/or the central column (e.g., the Y-axis of the bump map) of the bump map. For example, as shown in FIG. 12, the bump structures for control signal pairing can be placed on the X-axis of the bump map. In the operation 1210, subsets of different bump structures (e.g., TX/RX, etc.) can be disposed symmetrically with respect to the X-axis and/or the Y-axis of the bump map.

In operation 1220, the D2D compiler (e.g., 320) can place subsets of different bump structures (e.g., TX/RX, TX/RX RP, TX/RX D2D clk, etc.) symmetrically on a bump map. For example, as shown in FIG. 12, the bump structures for TX can be disposed symmetrically to the bump structures for RX with respect to the Y-axis of the bump map. Shown in the operation 1220 of FIG. 12 is a non-limiting example, and any of bump structures can be symmetrically disposed.

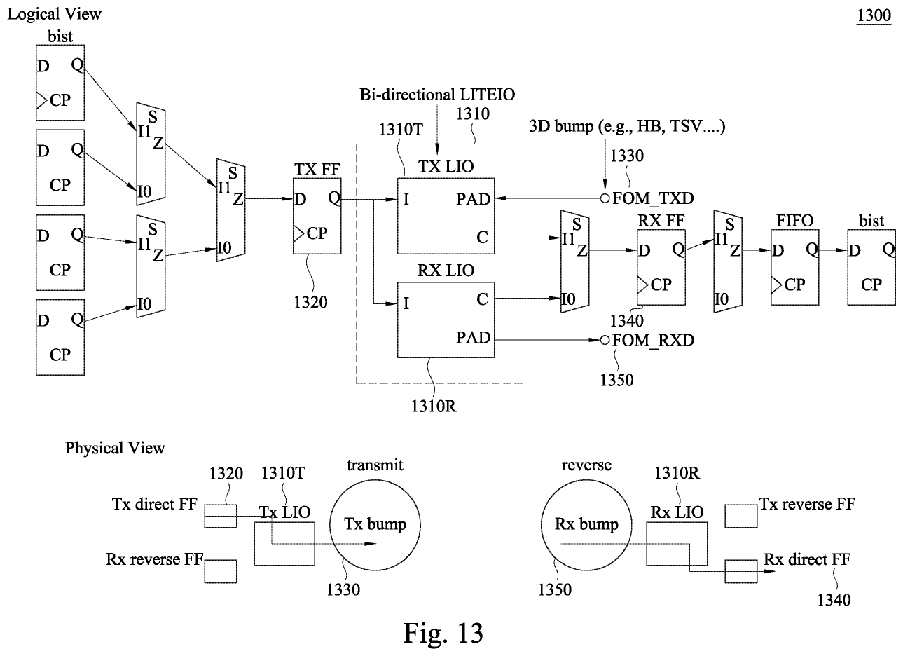

FIG. 13 illustrates an example operation 1300 for configuring bump maps, in accordance with some embodiments. The D2D compiler (e.g., 320) can use different logic configurations for connecting different bump structures. Shown in FIG. 13 is a configuration with a “direct” logic to connect bump structures for transmitting/receiving signals (e.g., TX/RX). In this configuration, a bi-directional LITEIO 1310 can be used to transmit/receive signals. The bi-directional LITEIO 1310 includes TX LIO 1310T configured to receive a signal from TX FF 1320 and provide the signal to a TX bump structure 1330, which then can transmit the signal. A RX bump structure 1350 can receive a signal (e.g., from a TX bump structure) and provide the signal to a RX LIO 1310R of the bi-directional LITEIO 1310, which then can provide the signal to RX FF 1340. In some examples, the RX LIO 1310R can provide the signal to the RX FF 1340 via a multiplexer.

FIG. 14 illustrates an example operation 1400 for configuring bump maps, in accordance with some embodiments. The D2D compiler (e.g., 320) can use different logic configurations for connecting different bump structures. Shown in the operation 1400 of FIG. 14 is a configuration with a “reverse” logic to connect bump structures for transmitting/receiving signals (e.g., TX/RX). A TX bump structure 1430 generated based on configurations with the “reverse” logic can receive signals, and a RX bump structure 1450 generated based on configurations with the “reverse” logic can transmit signals. In the configurations with the “reverse” logic, the TX bump structure 1430 can provide a received signal to TX LIO 1410T of a bi-directional LITEIO 1410, which can provide the signal to RX reverse FF 1420. In the configurations with the “reverse” logic, Tx reverse FF 1440 can provide a signal to the RX bump structure 1450 via RX LIO 1410R of the bi-directional LITEIO 1410, and the RX bump structure 1450 can transmit the signal. As discussed above with respect to FIG. 6 and FIG. 7, different logics (e.g., the “direct” logic, the “reverse” logic, etc.) can be configured to generate bump maps with different arrangements.

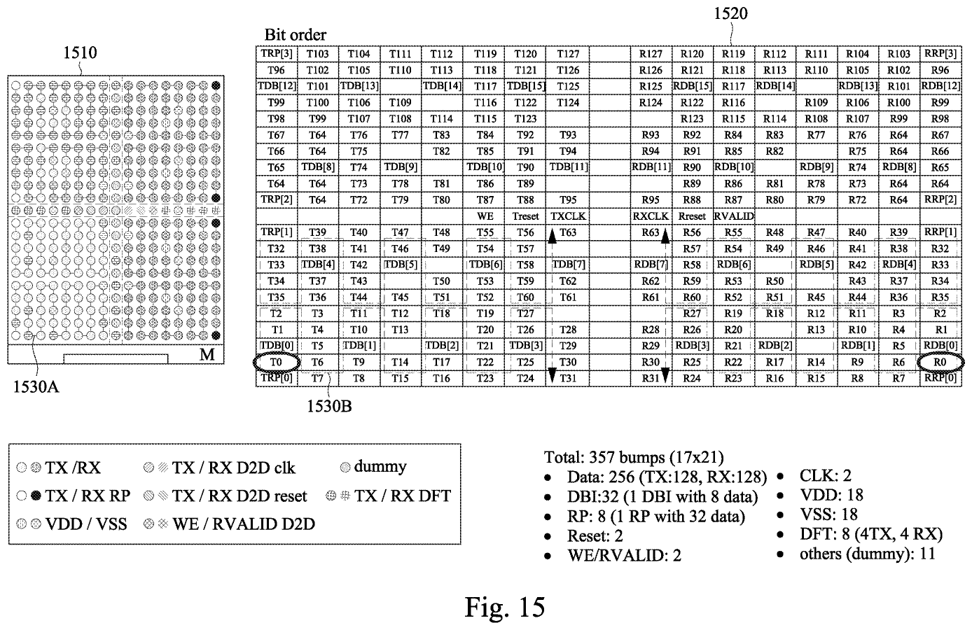

FIG. 15 illustrates an example bump map 1510 and a corresponding bit map 1520, in accordance with some embodiments. The bump map 1510 can be generated using various operations discussed with respect to FIG. 7 to FIG. 14. The bit map 1520 shows bits, each of which corresponds to each bump structure in the bump map 1510. In this non-limiting example, the bump map 1510 includes 357 bump structures (17×21), in which 256 bump structures are for TX/RX, 32 bump structures are for DBI, 8 bump structures are for TX/RX RP, 2 bump structures are for reset, 2 bump structures are for WE/RVALID, 2 bump structures are for TX/RX D2D clk, 18 bump structures are for VDD, 18 bump structures are for VSS, 8 bump structures are for TX/RX DFT, and 11 dummy bump structures are included.

The configurations (e.g., 310) to generate the bump map 1510 can include ordering 1530A of the bump structures. The bits in the bit map 1520 can be ordered based on the ordering 1530A of the bump structures. As shown in FIG. 15, ordering 1530B of the bits in the bit map 1520 can be generated based on the ordering 1530A to line up the bump structures (e.g., from T0 to T31, T32 to T63, . . . ). Likewise, the bump structures for RX can be lined up based on ordering.

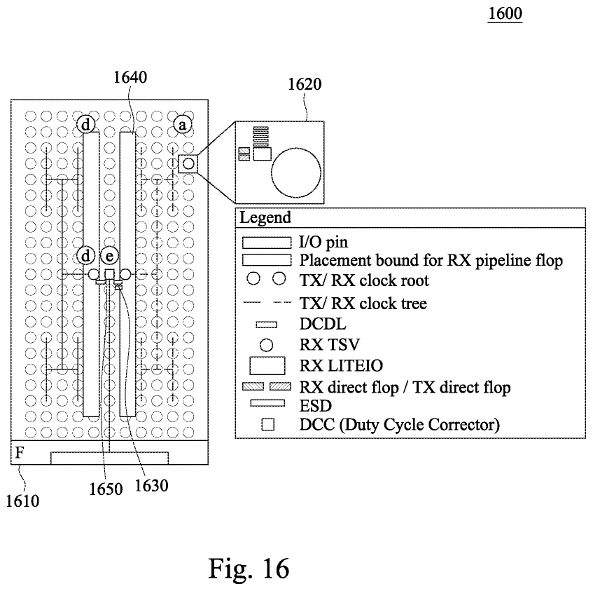

FIG. 16 illustrates example operations 1600 for designing a physical bump map, in accordance with some embodiments. The D2D compiler (e.g., 320) and/or a place and route tool operatively coupled thereto can generate recipes (e.g., 330) for physical layout design for a semiconductor package (e.g., a D2D interface block) based on configuration, a netlist, bump maps, etc. The D2D compiler and/or a place and route tool operatively coupled thereto can place or pre-place different components on a bump map 1610, and/or include recipes for clock tree synthesis (CTS) for D2D timing closure, to generate a physical layout design for a semiconductor package (e.g., a D2D interface block).

In the operation 1600, the D2D compiler (e.g., 320) can place or pre-place through-silicon via (TSV) related elements 1620, including LITEIO, ESD, and TX/RX flops. Examples of the TSV-related elements 1620 includes, but not limited to, RX TSV, RX LITEIO, RX direct flop, TX reverse flop, etc. In the operation 1600, the D2D compiler (e.g., 320) can place or pre-place clock components (e.g., H-tree clock roots, arch-clock multiplexer, etc.). All D2D and flops can be balanced together. In the operation 1600, the D2D compiler (e.g., 320) can place or pre-place digital-controlled delay line (DCDL) 1630 according to a closest logic-connectivity sequence. In the operation 1600, the D2D compiler (e.g., 320) can place or pre-place bounds 1640 for RX pipeline flops to guide an R2R timing. In the operation 1600, the D2D compiler (e.g., 320) can place or pre-place a duty-cycle corrector 1650 to restore duty cycle performance to improve clock frequency at a double-data rate.

In one aspect of the present disclosure, an integrated circuit design implementation system is disclosed. The system includes a die-to-die (D2D) complier configured to receive a configuration of a semiconductor package, the semiconductor package including at least a first semiconductor die and a second semiconductor die bonded to each other; and generate, based on the configuration of the semiconductor package, a first bump map and a second bump map for the first semiconductor die and the second semiconductor die, respectively. The first bump map indicates respective locations of a plurality of first bump structures of the first semiconductor die, and the second bump map indicates respective locations of a plurality of second bump structures of the second semiconductor die. In the first bump map, a first subset of the first bump structures configured for transmitting signals to the second semiconductor die and a second subset of the first bump structures configured for receiving signals from the second semiconductor die are disposed symmetrically to each other with respect to an X-axis or a Y-axis of the first bump map. In the second bump map, a first subset of the second bump structures configured for transmitting signals to the first semiconductor die and a second subset of the second bump structures configured for receiving signals from the first semiconductor die are disposed symmetrically to each other with respect to an X-axis or a Y-axis of the second bump map.

In another aspect of the present disclosure, a method for simulating a semiconductor package is disclosed. The method includes receiving a configuration of a semiconductor package, the semiconductor package including at least a first semiconductor die and a second semiconductor die bonded to each other; and generating, based on the configuration of the semiconductor package, a first bump map and a second bump map for the first semiconductor die and the second semiconductor die, respectively. The first bump map indicates respective locations of a plurality of first bump structures of the first semiconductor die, and the second bump map indicates respective locations of a plurality of second bump structures of the second semiconductor die. In the first bump map, a first subset of the first bump structures configured for transmitting signals to the second semiconductor die and a second subset of the first bump structures configured for receiving signals from the second semiconductor die are disposed symmetrically to each other with respect to an X-axis or a Y-axis of the first bump map. In the second bump map, a first subset of the second bump structures configured for transmitting signals to the first semiconductor die and a second subset of the second bump structures configured for receiving signals from the first semiconductor die are disposed symmetrically to each other with respect to an X-axis or a Y-axis of the second bump map.

In yet another aspect of the present disclosure, a computer program product is disclosed. The computer program product includes a computer-readable program medium code stored thereupon, the code, when executed by a processor, causing the processor to implement a method. The method includes receiving a configuration of a semiconductor package, the semiconductor package including at least a first semiconductor die and a second semiconductor die bonded to each other, wherein the first semiconductor die and the second semiconductor die are bonded such that the first semiconductor die and the second semiconductor die are arranged side-by-side or vertically stacked to one another; and generating, based on the configuration of the semiconductor package, a first bump map and a second bump map for the first semiconductor die and the second semiconductor die, respectively. The first bump map indicates respective locations of a plurality of first bump structures of the first semiconductor die, and the second bump map indicates respective locations of a plurality of second bump structures of the second semiconductor die. In the first bump map, a first subset of the first bump structures configured for transmitting signals to the second semiconductor die and a second subset of the first bump structures configured for receiving signals from the second semiconductor die are disposed symmetrically to each other with respect to an X-axis or a Y-axis of the first bump map. In the second bump map, a first subset of the second bump structures configured for transmitting signals to the first semiconductor die and a second subset of the second bump structures configured for receiving signals from the first semiconductor die are disposed symmetrically to each other with respect to an X-axis or a Y-axis of the second bump map.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit design implementation system, comprising:
a die-to-die (D2D) complier configured to:
receive a configuration of a first semiconductor die and a second semiconductor die in a semiconductor package; and
generate, based on the configuration, a first bump map and a second bump map for the first semiconductor die and the second semiconductor die, respectively;
wherein the first bump map indicates respective locations of a plurality of first bump structures of the first semiconductor die, and the second bump map indicates respective locations of a plurality of second bump structures of the second semiconductor die;
wherein, in the first bump map, the first bump structures are arranged symmetrically according to respective functions of the first bump structures, and in the second bump map, the second bump structures are arranged symmetrically according to respective functions of the second bump structures.

2. The integrated circuit design implementation system of claim 1,
wherein, in the first bump map, a first subset of the first bump structures configured to perform a first function and a second subset of the first bump structures configured to perform a second function are disposed symmetrically to each other with respect to an X-axis or a Y-axis of the first bump map; and
wherein, in the second bump map, a first subset of the second bump structures configured to perform the first function and a second subset of the second bump structures configured to perform the second function are disposed symmetrically to each other with respect to an X-axis or a Y-axis of the second bump map.

3. The integrated circuit design implementation system of claim 2, wherein the first function includes transmitting a signal to another semiconductor die, and the second function includes receiving a signal from another semiconductor die.

4. The integrated circuit design implementation system of claim 2,
wherein, in the first bump map, a third subset of the first bump structures configured for transmitting/receiving first control signals are disposed on the X-axis or the Y-axis of the first bump map; and
wherein, in the second bump map, a third subset of the second bump structures configured for transmitting/receiving second control signals are disposed on the X-axis or the Y-axis of the second bump map.

5. The integrated circuit design implementation system of claim 4,
wherein, in the first bump map, a fourth subset of the first bump structures configured for receiving a first supply voltage are disposed in parallel with the X-axis of the first bump map, where the fourth subset of first bump structures are spaced from one another with a first distance; and
wherein, in the second bump map, a fourth subset of the second bump structures configured for receiving the first supply voltage are disposed in parallel with the X-axis of the second bump map, where the fourth subset of second bump structures are spaced from one another with the first distance.

6. The integrated circuit design implementation system of claim 5,
wherein, in the first bump map, a fifth subset of the first bump structures configured for receiving a second supply voltage are disposed in parallel with the X-axis of the first bump map, where the fifth subset of first bump structures are spaced from one another with a second distance; and
wherein, in the second bump map, a fifth subset of the second bump structures configured for receiving the second supply voltage are disposed in parallel with the X-axis of the second bump map, where the fifth subset of second bump structures are spaced from one another with the second distance.

7. The integrated circuit design implementation system of claim 6, wherein the first distance is different from the second distance.

8. The integrated circuit design implementation system of claim 2,
wherein the first subset of the first bump structures further configured as a plurality of first repair chains are each disposed in a corresponding first zone of the first bump map, and the second subset of the first bump structures further configured as a plurality of second repair chains are each disposed in a corresponding second zone of the first bump map, the first zone and the second zone each occupying M times an area unit of the first bump map, M being a positive integer; and
wherein the first subset of the second bump structures further configured as a plurality of third repair chains are each disposed in a corresponding third zone of the second bump map, and the second subset of the second bump structures further configured as a plurality of fourth repair chains are each disposed in a corresponding fourth zone of the second bump map, the third zone and the fourth zone each occupying N times an area unit of the second bump map, N being a positive integer.

9. The integrated circuit design implementation system of claim 2,
wherein the first subset and the second subset of the first bump structures further configured as a plurality of first Dynamic Bus Inversion (DBI) signals are each disposed in a corresponding first zone of the first bump map, the first zone each occupying M times an area unit of the first bump map, M being a positive integer; and
wherein the first subset and the second subset of the second bump structures further configured as a plurality of second DBI signals are each disposed in a corresponding second zone of the second bump map, the second zone each occupying N times an area unit of the second bump map, N being a positive integer.

10. The integrated circuit design implementation system of claim 1, wherein the configuration of the semiconductor package includes the following information for each of the first and second semiconductor dies: a number of data bits; a size of a bump matrix; a repair-data ratio; a Dynamic Bus Inversion (DBI)-data ratio; or a Power Ground (PG) ratio.

11. A method for simulating a semiconductor package, comprising:
receiving a configuration of a first semiconductor die and a second semiconductor die in a semiconductor package; and
generating, based on the configuration, a first bump map and a second bump map for the first semiconductor die and the second semiconductor die, respectively;
wherein the first bump map indicates respective locations of a plurality of first bump structures of the first semiconductor die, and the second bump map indicates respective locations of a plurality of second bump structures of the second semiconductor die;
wherein, in the first bump map, the first bump structures are arranged symmetrically according to respective functions of the first bump structures, and in the second bump map, the second bump structures are arranged symmetrically according to respective functions of the second bump structures.

12. The method of claim 11, wherein the first semiconductor die and the second semiconductor die are bonded such that the first semiconductor die and the second semiconductor die are arranged side-by-side.

13. The method of claim 11,
wherein, in the first bump map, a first subset of the first bump structures configured to perform a first function and a second subset of the first bump structures configured to perform a second function are disposed symmetrically to each other with respect to an X-axis or a Y-axis of the first bump map; and
wherein, in the second bump map, a first subset of the second bump structures configured to perform the first function and a second subset of the second bump structures configured to perform the second function are disposed symmetrically to each other with respect to an X-axis or a Y-axis of the second bump map.

14. The method of claim 13, wherein the first function includes transmitting a signal to another semiconductor die, and the second function includes receiving a signal from another semiconductor die.

15. The method of claim 11, wherein the first semiconductor die and the second semiconductor die are bonded such that the first semiconductor die is vertically stacked on the second semiconductor die.

16. A computer program product comprising a computer-readable program medium code stored thereupon, the code, when executed by a processor, causing the processor to implement a method, comprising:
receiving a configuration of a first semiconductor die and a second semiconductor die in a semiconductor package, wherein the first semiconductor die and the second semiconductor die are bonded such that the first semiconductor die and the second semiconductor die are arranged side-by-side or vertically stacked to one another; and
generating, based on the configuration, a first bump map and a second bump map for the first semiconductor die and the second semiconductor die, respectively;
wherein the first bump map indicates respective locations of a plurality of first bump structures of the first semiconductor die, and the second bump map indicates respective locations of a plurality of second bump structures of the second semiconductor die;
wherein, in the first bump map, the first bump structures are arranged symmetrically according to respective functions of the first bump structures, and in the second bump map, the second bump structures are arranged symmetrically according to respective functions of the second bump structures.

17. The computer program product of claim 16,
wherein, in the first bump map, a first subset of the first bump structures configured to perform a first function and a second subset of the first bump structures configured to perform a second function are disposed symmetrically to each other with respect to an X-axis or a Y-axis of the first bump map; and
wherein, in the second bump map, a first subset of the second bump structures configured to perform the first function and a second subset of the second bump structures configured to perform the second function are disposed symmetrically to each other with respect to an X-axis or a Y-axis of the second bump map.

18. The computer program product of claim 17,
wherein the first function includes transmitting a signal to another semiconductor die, and the second function includes receiving a signal from another semiconductor die.

19. The computer program product of claim 16,
wherein, in the first bump map, a fifth subset of the first bump structures configured for receiving a second supply voltage are disposed in parallel with an axis of the first bump map, where the fifth subset of first bump structures are spaced from one another with a second distance; and
wherein, in the second bump map, a fifth subset of the second bump structures configured for receiving the second supply voltage are disposed in parallel with the X-axis of the second bump map, where the fifth subset of second bump structures are spaced from one another with the second distance.

20. The computer program product of claim 16,
wherein the semiconductor package further comprises a third semiconductor die, wherein the first semiconductor die, the second semiconductor die, and the third semiconductor die are vertically stacked to one another,
wherein the processor to implement a method, comprising generating, based on the configuration of the semiconductor package, a third bump map for the third semiconductor die.
